(19) United States
(12) Patent Application Publication
(10) Pub. No.: US 2024/0387301 A1
(43) Pub. Date: Nov. 21, 2024

(54) SUBSTRATE PROCESSING SYSTEM AND FILM THICKNESS MEASURING METHOD

(71) Applicant: Tokyo Electron Limited, Tokyo (JP)

(72) Inventors: Hirokazu KYOKANE, Yamanashi (JP); Satoshi TANAKA, Yamanashi (JP)

(21) Appl. No.: 18/429,645

(22) Filed: Feb. 1, 2024

(30) Foreign Application Priority Data
Feb. 7, 2023 (JP) 2023-017114

(51) Int. Cl. H01L 21/66; G01B 11/06

(52) U.S. Cl. CPC H01L 22/26; G01B 11/0625; G01B 2210/56

(57) ABSTRACT

A substrate processing system includes a substrate support that supports an outer edge of a substrate having a first surface and a second surface opposite to the first surface, a processing container that accommodates the substrate and the substrate support to perform a substrate processing on the substrate, and a substrate transfer unit that transfers the substrate. Further, the substrate processing system includes a measurement unit that measures an index related to a film thickness of a film stacked on the second surface, and an estimation unit that calculates the film thickness of the film on the second surface based on the measured index related to the film thickness of the film on the second surface and calculates a film thickness of a film stacked on the first surface based on the calculated film thickness of the film on the second surface.

### CROSS-REFERENCE TO RELATED APPLICATIONS

The present application is based on and claims priority from Japanese Patent Application No. 2023-017114, filed on Feb. 7, 2023, with the Japan Patent Office, the disclosure of which is incorporated herein in its entirety by reference.

### TECHNICAL FIELD

The present disclosure relates to a substrate processing system and a film thickness measuring method.

### BACKGROUND

Substrate processing apparatuses or film forming apparatuses have been known in which a film formation processing is performed on a substrate by heating the substrate to an appropriate temperature and supplying a predetermined gas to a processing container while a plurality of substrates are accommodated side by side inside the processing container.

Japanese Patent Application Laid-open Publication No. 2003-007789 discloses a substrate processing apparatus having a film thickness measuring device that measures the film thickness of a substrate after film formation. The film thickness measuring device is positioned above a transfer path of the substrate and measures the thickness of a film formed on the upper surface of the substrate.

### SUMMARY

According to an aspect of the present disclosure, there is provided a substrate processing system including a substrate support that supports an outer edge of a substrate having a first surface and a second surface opposite to the first surface, a processing container that accommodates the substrate and the substrate support to perform a substrate processing on the substrate, and a substrate transfer unit that transfers the substrate subjected to the substrate processing. The substrate processing system further includes a measurement unit that is provided on a transfer path along which the substrate is transferred by the substrate transfer unit and that measures an index related to a film thickness of a film stacked on the second surface, and a estimation unit that calculates the film thickness of the film on the second surface based on the measured index related to the film thickness of the film on the second surface and to calculate a film thickness of a film stacked on the first surface based on the calculated film thickness of the film on the second surface.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view schematically illustrating a substrate processing apparatus applied to a substrate processing system according to an embodiment.

FIG. 2 is a perspective view schematically illustrating the substrate processing system.

FIG. 3A is a side view illustrating the lower surface side film thickness measurement of a substrate by a measurement unit.

FIG. 3B is a plan view illustrating the lower surface side film thickness measurement of the substrate by the measurement unit.

FIG. 4 is a diagram illustrating an example of a hardware configuration of a control unit.

FIG. 5A is a side cross-sectional view schematically illustrating the substrate after substrate processing, and FIG. 5B is a graph illustrating a relationship between the film thickness of a lower surface side film and the film thickness of an upper surface side film.

FIG. 6 is a block diagram illustrating functional parts in the control unit that measures the film thickness of the substrate.

FIG. 7 is a flowchart illustrating the processing flow of a film thickness measuring method.

FIG. 8 is a graph illustrating a reflection spectrum of the substrate measured by the measurement unit.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for carrying out the present disclosure will be described with reference to the drawings. In each drawing, the same reference numerals may be given to the same components, and redundant descriptions may be omitted.

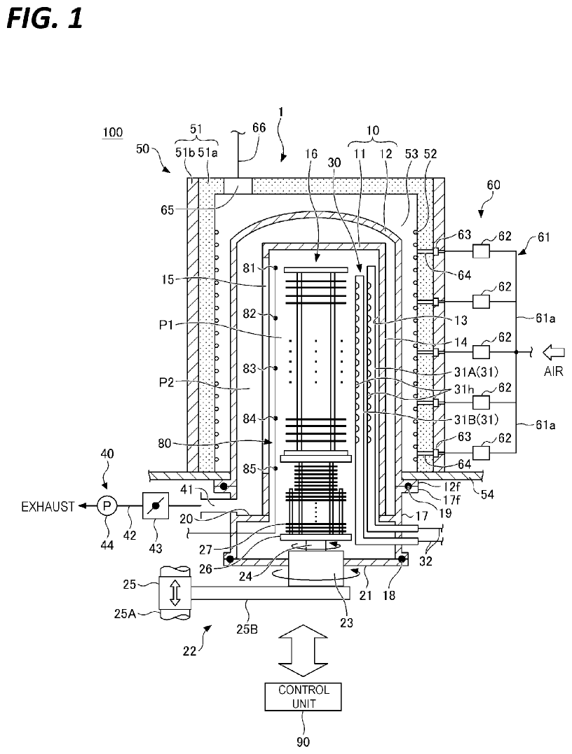

FIG. 1 is a cross-sectional view schematically illustrating a substrate processing apparatus 1 applied to a substrate processing system 100 according to an embodiment. To facilitate the understanding of the substrate processing system 100, the substrate processing apparatus 1, which actually performs a substrate processing in the substrate processing system 100, will first be described with reference to FIG. 1.

### [Configuration of Substrate Processing Apparatus 1]

The substrate processing apparatus 1 is configured as a vertical film forming apparatus (heat treatment apparatus) that holds a plurality of substrates W side by side in the vertical direction and forms a desired film on a surface of each substrate W by atomic layer deposition (ALD), chemical vapor deposition (CVD), thermal oxidation, or other methods. The substrate W subjected to film formation is not particularly limited but may be, for example, a silicon wafer, a semiconductor substrate such as a compound semiconductor wafer, or a glass substrate.

The substrate processing apparatus 1 includes a processing container 10 in which each substrate W is accommodated and subjected to film formation, a gas supply unit 30 that supplies gases to the inside of the processing container 10, a gas exhaust unit 40 that exhausts the gases from the inside of the processing container 10, and a temperature regulation furnace 50 arranged around the processing container 10. Further, the substrate processing system 100 includes a control unit 90 that controls each component of the substrate processing apparatus 1.

The processing container 10 is formed in a cylindrical shape and is installed such that the axis thereof is along the vertical direction (up-and-down direction). Further, the processing container 10 has a double-cylinder structure including an inner cylinder 11 and an outer cylinder 12 accommodating the inner cylinder 11. The inner and outer cylinders 11 and 12 are made of a heat-resistant material such as quartz, and are arranged coaxially with each other. The processing container 10 is not limited to a double-cylinder structure but may have a single-cylinder structure or even a structure composed of three or more cylinders.

The inner cylinder 11 has an open lower end and a ceiling wall at an upper end thereof. Further, the inner cylinder 11 has an inner diameter larger than the diameter of each substrate W and also has an axial length longer than the vertical arrangement range of each substrate W. The inside of the inner cylinder 11 is a processing space P1 in which gases are supplied to each accommodated substrate W for film formation. The inner cylinder 11 is provided at a predetermined circumferential position thereof with an opening 15 to allow the gases to flow out from the processing space P1 to a distribution space P2 between the inner cylinder 11 and the outer cylinder 12. For example, the vertical length of the opening 15 is set to be equal to or greater than the arrangement range of each substrate W. The formation position of the opening 15 is not particularly limited, and for example, the opening 15 may be formed in the ceiling wall of the inner cylinder 11.

Further, the inner cylinder 11 is provided at a circumferential position opposite to the opening 15 with an accommodating region 13, which communicates with the processing space P1 and is capable of accommodating a gas supply nozzle 31 of the gas supply unit 30. The accommodating region 13 extends parallel to the axis (vertical direction) of the inner cylinder 11. As an example, the accommodating region 13 is defined inside a protrusion 14, which is a radially outwardly protruding portion of a sidewall of the inner cylinder 11.

The outer cylinder 12 has an inner diameter larger than that of the inner cylinder 11 and covers the inner cylinder 11 in a non-contact manner. The distribution space P2 formed inside the outer cylinder 12 is continuous to the upper side and lateral side of the inner cylinder 11 and allows the gases moved from the opening 15 to distribute vertically downward.

A lower end of the processing container 10 is supported by a cylindrical manifold 17 made of stainless steel. The manifold 17 has a manifold-side flange 17f at an upper end thereof. The manifold-side flange 17f anchors and supports an outer cylinder-side flange 12f formed at a lower end of the outer cylinder 12. A seal member 19 is sandwiched between the outer cylinder-side flange 12f and the manifold-side flange 17f to airtightly seal the outer cylinder 12 and the manifold 17. Further, the manifold 17 includes an annular support plate 20 on an upper inner wall thereof. The support plate 20 protrudes radially inward from the inner wall to anchor and support the lower end of the inner cylinder 11.

A lid 21 of a substrate placement unit 22 is removably arranged in a lower end opening of the manifold 17. The manifold 17 is provided at a lower end thereof with a seal member 18, which airtightly blocks the lower end opening of the manifold 17 when coming into contact with the lid 21.

The substrate placement unit 22 includes a wafer boat 16 extending in the vertical direction to protrude upward from the lid 21. The wafer boat 16 has a plurality of shelves (not illustrated) along the vertical direction, and each shelf holds the outer edge of each substrate W. In a state where the respective substrates W are held by the wafer boat 16, the respective substrates W are arranged at a predetermined interval along the vertical direction and are supported horizontally with respect to each other.

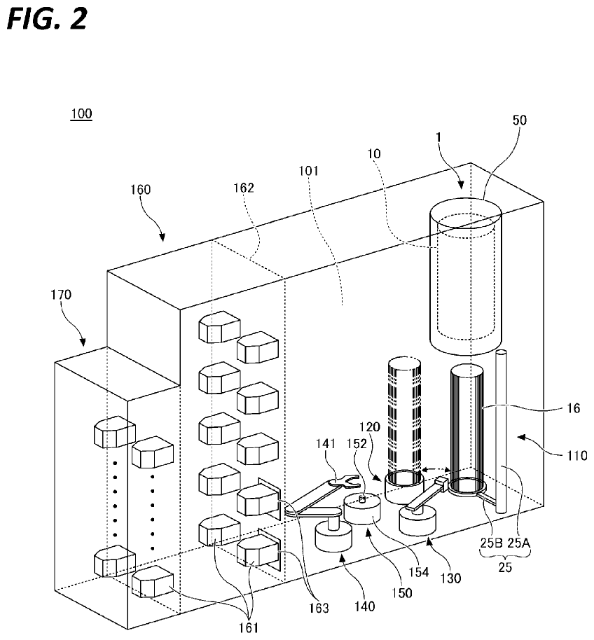

Furthermore, in addition to the wafer boat 16 and the lid 21, the substrate placement unit 22 includes a rotation mechanism 23 for rotatably supporting the wafer boat 16, an elevation mechanism 25, and an insulating structure 27. The rotation mechanism 23 and the elevation mechanism 25 constitute a boat actuator 110 to be described later in the substrate processing system 100 (see also FIG. 2).

The rotation mechanism 23 is located at the center of the lid 21, and includes a rotation source (not illustrated), a rotating shaft 24 rotated by the rotation source, and a rotating plate 26 connected to an upper end of the rotating shaft 24. The wafer boat 16 is mounted on the upper surface of the rotating plate 26 via the insulating structure 27. The rotating shaft 24 and the rotating plate 26 rotate the insulating structure 27 and the wafer boat 16 around the rotational axis under the rotation of the rotation mechanism 23.

The elevation mechanism 25 includes a column 25A extending in the vertical direction, an arm 25B capable of being raised and lowered relative to the column 25A, and an elevation driving unit (not illustrated) for raising and lowering the arm 25B. The arm 25B extends approximately horizontally, and supports members (wafer boat 16, rotating plate 26, and insulating structure 27) at the upper side of the lid 21, rotation mechanism 23 and rotating shaft 24. The substrate processing apparatus 1 vertically moves these members at the upper side of the lid 21, rotation mechanism 23, and rotating shaft 24 in unison by raising and lowering the arm 25B of the elevation mechanism 25, thus inserting and releasing the wafer boat 16 into and from the processing container 10.

The gas supply unit 30 includes one or more gas supply nozzles 31 to supply gases to each substrate W inside the processing space P1 of the processing container 10. The gases supplied by the gas supply unit 30 include a raw material gas for depositing a precursor on the substrate W, a reaction gas for reacting with the precursor, and a purge gas for purging the inside of the processing space P1.

In the present embodiment, the gas supply unit 30 includes two gas supply nozzles 31 (first gas supply nozzle 31A and second gas supply nozzle 31B). The first gas supply nozzle 31A is a nozzle that supplies the raw material gas and purge gas into the processing container 10. The second gas supply nozzle 31B is a nozzle that supplies the reaction gas into the processing container 10. The gas supply unit 30 is not limited to this configuration but may, for example, include the gas supply nozzles 31 for each type of gas such as the raw material gas, reaction gas, and purge gas (i.e., three or more gas supply nozzles). Conversely, the gas supply unit 30 may be configured to supply the raw material gas, reaction gas, and purge gas through one gas supply nozzle 31.

Each gas supply nozzle 31 (first gas supply nozzle 31A and second gas supply nozzle 31B) is a quartz injector tube and is fixed to the manifold 17. Further, each gas supply nozzle 31 extends vertically inside the inner cylinder 11 and is bent into an L-shape at a lower end thereof to penetrate the manifold 17 upward and outward. Each gas supply nozzle 31 has a plurality of gas holes 31h at a predetermined interval in the vertical direction inside the inner cylinder 11, and discharges the gas horizontally from each gas hole 31h. The interval between the respective gas holes 31h is set, for example, to be the same as the interval between the respective substrates W supported by the wafer boat 16. Further, the vertical position of each gas hole 31h is set to be located in the middle between the vertically adjacent substrates W. This allows each gas hole 31h to smoothly supply the gas to a gap between the respective substrates W.

The gas supply unit 30 includes a plurality of gas supply channels 32 connected to each of the first gas supply nozzle 31A and the second gas supply nozzle 31B outside the processing container 10. The gas supply channel 32 connected to the first gas supply nozzle 31A is branched at an intermediate position and is connected to a raw material gas source and a purge gas source (both not illustrated). The gas supply channel 32 connected to the second gas supply nozzle 31B is connected to a reaction gas source (not illustrated). Further, each gas supply channel 32 is provided at intermediate positions leading to each gas source with a flow rate adjuster for adjusting the flow rate of the gas and a valve for opening and closing a flow path inside the channel (both not illustrated).

The gas exhaust unit 40 exhausts the gases inside the processing container 10 to the outside. The gas supplied by each gas supply nozzle 31 moves from the processing space P1 of the inner cylinder 11 to the distribution space P2 and is then exhausted through a gas outlet 41. The gas outlet 41 is formed in an upper sidewall of the manifold 17 above the support plate 20. An exhaust channel 42 of the gas exhaust unit 40 is connected to the gas outlet 41. The gas exhaust unit 40 is provided with a pressure adjustment valve 43 and a vacuum pump 44 in order from upstream to downstream of the exhaust channel 42. The gas exhaust unit 40 adjusts the pressure inside the processing container 10 by suctioning the gases inside the processing container 10 with the vacuum pump 44 and also, adjusting the flow rate of the exhausted gases with the pressure adjustment valve 43.

Further, a temperature sensor 80 is provided inside the processing container 10 (e.g., the processing space P1 inside the inner cylinder 11) to detect the temperature inside the processing container 10. The temperature sensor 80 has a plurality of (five in the present embodiment) temperature sensing elements 81 to 85 at different positions in the vertical direction. The plurality of temperature sensing elements 81 to 85 may employ thermocouples, temperature sensitive resistors, and others. The temperature sensor 80 transmits the temperatures detected by each of the plurality of temperature sensing elements 81 to 85 to the control unit 90.

Meanwhile, the temperature regulation furnace 50 covers the entire processing container 10 and heats and cools each substrate W accommodated in the processing container 10 from the outside. Specifically, the temperature regulation furnace 50 includes a cylindrical housing 51 with a ceiling and a heater 52 provided inside the housing 51.

The housing 51 is attached to the upper surface of a base plate 54 located at the boundary between the processing container 10 and the manifold 17 and heats the processing container 10 accommodated therein. The housing 51 is spaced apart from the processing container 10, thus forming a temperature regulation space 53 between the processing container 10 and the housing 51.

The housing 51 includes an insulating portion 51a that has a ceiling and covers the entire processing container 10 and a reinforcing portion 51b that reinforces the insulating portion 51a at the outer peripheral side of the insulating portion 51a. The insulating portion 51a is made mainly of, for example, silica, alumina, or others, and serves to prevent heat transfer. The reinforcing portion 51b is made of a metal such as stainless steel. Further, to minimize the impact of heat on the outside of the temperature regulation furnace 50, the outer peripheral side of the reinforcing portion 51b is covered with a water cooling jacket (not illustrated).

The heater 52 of the temperature regulation furnace 50 may be configured appropriately to heat the plurality of substrates W inside the processing container 10. For example, an infrared heater that radiates infrared rays to heat the processing container 10 may be used as the heater 52. In this case, the heater 52 is formed in a linear shape, and is held on an inner peripheral surface of the insulating portion 51a in a spiral, annular, arc, shank, or meandering shape through a holder (not illustrated).

Furthermore, the temperature regulation furnace 50 includes a cooler 60 that distributes a cooling gas such as air into the temperature regulation space 53 in order to cool the processing container 10 during or after film formation. The cooler 60 includes an external supply channel 61 and a flow rate adjuster 62, which are provided outside the temperature regulation furnace 50, a supply flow path 63 provided in the reinforcing portion 51b, and a supply hole 64 provided in the insulating portion 51a.

The external supply channel 61 is connected to a blower (not illustrated) and is branched into a plurality of branch channels 61a at an intermediate position. The flow rate adjuster 62 is provided for each of the plurality of branch channels 61a and adjusts the flow rate of air distributed through each branch channel 61a.

The supply flow path 63 is formed at a plurality of points along the axial direction (vertical direction) of the reinforcing portion 51b. Each of a plurality of supply flow paths 63 extends annularly along the circumferential direction inside the cylindrical reinforcing portion 51b in a planar cross-sectional view.

Each supply hole 64 is formed in a matrix shape along the axial and circumferential directions of the insulating portion 51a. Each supply hole 64 arranged in the axial direction is located at the same axial position as each supply flow path 63 arranged in the axial direction and communicates with each supply flow path 63 along the horizontal direction. Each supply hole 64 is formed to penetrate the insulating portion 51a and blows out the air introduced into each supply flow path 63 toward the temperature regulation space 53.

Further, the cooler 60 has an exhaust hole 65 in the ceiling of the housing 51 for discharging the air supplied into the temperature regulation space 53. The exhaust hole 65 is connected to an external exhaust channel 66 provided outside the housing 51.

In the above-described example, a film forming apparatus that supplies a raw material gas and reaction gas to each substrate W to form a desired film on a surface of each substrate W has been described. However, the substrate processing system 100 is not limited to applying a film forming apparatus as the substrate processing apparatus 1. For example, the substrate processing system 100 may apply an etching apparatus that etches a film formed on a surface of each substrate W as the substrate processing apparatus 1. In this case, the substrate processing apparatus 1 may have a component to generate a plasma inside the processing container 10.

### [Configuration of Substrate Processing System 100]

Next, the overall configuration of the substrate processing system 100 including the substrate processing apparatus 1 described above will be described with reference to FIG. 2. FIG. 2 is a perspective view schematically illustrating the substrate processing system 100.

In addition to the substrate processing apparatus 1, the substrate processing system 100 includes the boat actuator 110, boat stage 120, boat transfer unit 130, substrate transfer unit 140, measurement unit 150, interface 160, and load port 170.

The boat actuator 110 is provided at the lower side of the substrate processing apparatus 1 in the vertical direction and has the functions of raising and lowering the substrate placement unit 22 and of rotating the wafer boat 16. Therefore, the boat actuator 110 includes the above-described rotation mechanism 23 and elevation mechanism 25 (column 25A and arm 25B). The elevation mechanism 25 raises the arm 25B under the operation of the elevation driving unit, thereby loading the entire wafer boat 16 mounted on the arm 25B into the processing container 10. Further, the elevation mechanism 25 lowers the arm 25B under the operation of the elevation driving unit, thereby unloading the entire wafer boat 16 into a space at the lower side of the processing container 10 in the vertical direction.

The boat stage 120 causes the wafer boat 16 to stand by before or after substrate processing. The substrate processing system 100 transfers each substrate W to the wafer boat 16 and takes out each substrate W from the wafer boat 16, with the wafer boat 16 and the insulating structure 27 (see FIG. 1) standing by on the boat stage 120. The substrate processing system 100 has one boat stage 120 in the present embodiment, but may be configured to have a plurality of boat stages 120 as well as a number of wafer boats 16 corresponding to the number of boat stages 120.

The boat transfer unit 130 has a rotatable transfer device and transfers the wafer boat 16 and the insulating structure 27 between the boat actuator 110 and the boat stage 120.

The substrate transfer unit 140 transfers the substrate W between the wafer boat 16 standing by on the boat stage 120 and the interface 160. For example, the substrate transfer unit 140 may employ a multi-joint robot having a plurality of arms and a pick 141 that directly holds the substrate W. Although FIG. 2 illustrates the substrate transfer unit 140 provided with one pick 141, the substrate transfer unit 140 may be configured with a plurality (e.g., five) picks 141 to simultaneously transfer a plurality of substrates W.

The measurement unit 150 is provided on a transfer path for the transfer of the substrate W by the substrate transfer unit 140 (between the boat stage 120 and the interface 160) to measure the film thickness of the substrate W. In particular, the measurement unit 150 according to the present embodiment is configured to measure the thickness of a film formed on the lower surface (back surface) of the substrate W.

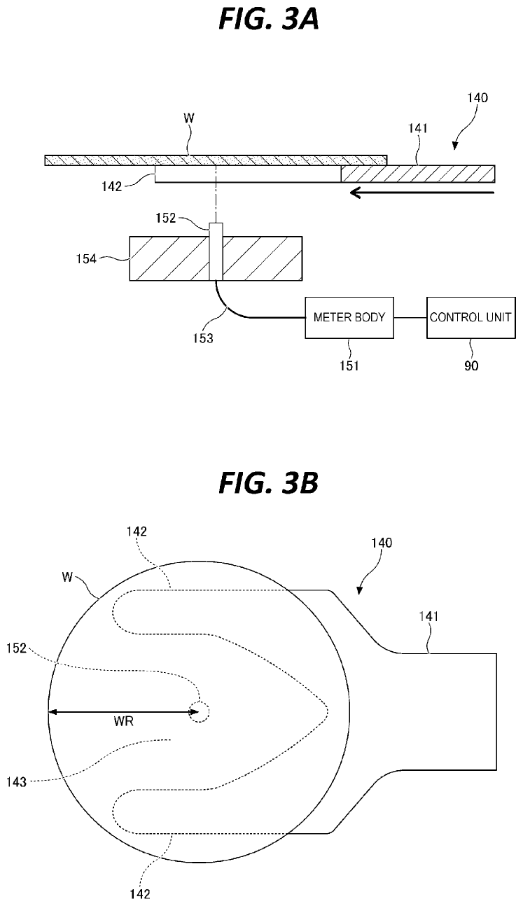

FIG. 3A is a side view illustrating the lower surface side film thickness measurement of the substrate W by the measurement unit 150. FIG. 3B is a plan view illustrating the lower surface side film thickness measurement of the substrate W by the measurement unit 150. As illustrated in FIGS. 3A and 3B, the measurement unit 150 employs a meter capable of measuring the lower surface side film thickness of the substrate W. This type of meter is a spectroscopic interference film thickness meter, for example. In this case, the measurement unit 150 includes a meter body 151, a probe 152, and a fiber wire 153 connecting the meter body 151 and the probe 152.

The meter body 151 includes a light source that emits measurement light, a spectrometer that spectrally disperses reflected light, and an analyzer that analyzes the spectrally dispersed reflection spectrum (both not illustrated). The fiber wire 153 transmits the measurement light from the light source of the meter body 151 to the probe 152 and also transmits the reflected light received by the probe 152 to the spectrometer of the meter body 151. The probe 152 is firmly supported by a platform 154 of the substrate processing system 100 and protrudes vertically upward. The probe 152 is provided at an upper end thereof with an optical lens that emits measurement light and receives the light reflected from the substrate W.

The substrate transfer unit 140 transfers the substrate W by holding the lower surface of the substrate W with a pair of tip extensions 142 bifurcated from the pick 141. A space 143 is formed between the pair of tip extensions 142, and the probe 152 of the measurement unit 150 may emit the measurement light to the center of the lower surface of the substrate W through the space 143. Further, the substrate processing system 100 may transfer the substrate W such that a portion of the substrate W from the outer edge to the center thereof passes through the space 143 between the pair of tip extensions 142, thereby measuring the distribution of film thickness within the radial range WR from the outer edge to the center of the substrate W by the measurement unit 150.

The analyzer of the meter body 151 analyzes the spectrally dispersed reflection spectrum by the spectrometer, and transmits information on this reflection spectrum to the control unit 90 as an index related to the film thickness of the substrate W. The control unit 90 calculates the thickness of a film formed on the lower surface of the substrate W based on the reflection spectrum information, and also estimates (calculates) the thickness of a film formed on the upper surface of the substrate W based on the calculated thickness of the film on the lower surface of the substrate W. This method of measuring the film thickness of the substrate W will be described later in detail.

Returning to FIG. 2, in the substrate processing system 100, the above boat actuator 110, boat stage 120, boat transfer unit 130, substrate transfer unit 140, and measurement unit 150 are arranged inside the same lower space 101 at the lower side of the substrate processing apparatus 1 in the vertical direction. The substrate processing system 100 includes a pressure adjuster (not illustrated) capable of adjusting the internal pressure of the lower space 101 and may adjust the internal pressure of the lower space 101 to a desired pressure by the pressure adjuster. As an example, the substrate processing system 100 may reduce the pressure of the lower space 101 to a vacuum atmosphere. The substrate processing system 100 may separate each component arranged in the lower space 101 by a divider (not illustrated).

The interface 160 of the substrate processing system 100 is provided in a different compartment from the lower space 101 and stores a plurality of substrate storage containers 161 each accommodating a plurality of (e.g., 25) substrates W. An example of the substrate storage container 161 may be a front-opening unified pod (FOUP).

The lower space 101 and the interface 160 are separated by a partition 162. The partition 162 has one or more ports 163 through which the substrate storage containers 161 may be exposed to the lower space 101. Further, the interface 160 has a transfer unit (not illustrated) that transfers an appropriate substrate storage container 161 among the plurality of substrate storage containers 161 to the port 163. This interface 160 may employ one based on a front-opening interface mechanical standard (FIMS) system, which is a mechanical standard. The measurement unit 150 may be configured by installing the probe 152 to the port 163 of the interface 160. Alternatively, the measurement unit 150 may be provided in place of any one port 163 among a plurality of ports 163.

The load port 170 is a port for loading and unloading the substrate storage container 161 into and out of the above-described interface 160. The load port 170 may be configured to store the plurality of substrate storage containers 161 in advance, as illustrated in FIG. 2.

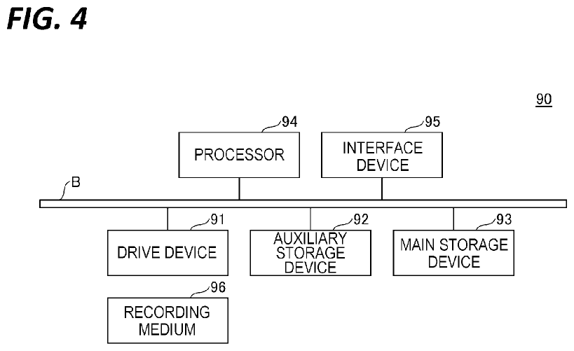

The control unit 90 of the above substrate processing system 100 controls the operation of each component of the substrate processing system 100. FIG. 4 is a diagram illustrating an example of a hardware configuration of the control unit 90. As illustrated in FIG. 4, the control unit 90 is a computer that includes a drive device 91, an auxiliary storage device 92, a main storage device 93, a processor 94, and an interface device 95, among others, each of which is interconnected by a bus B. A program that implements the processing of the control unit 90 is provided by a recording medium 96 such as a CD-ROM. When the recording medium 96 storing the program is set in the drive device 91, the program is installed from the recording medium 96 to the auxiliary storage device 92 through the drive device 91. However, the program does not necessarily need to be installed from the recording medium 96 but may be downloaded from another computer via a network. The auxiliary storage device 92 stores the installed program, recipes and other necessary data. When there is an instruction to start the program, the main storage device 93 reads and stores the program from the auxiliary storage device 92. The processor 94 executes functions related to the substrate processing system 100 according to the program stored in the main storage device 93. The interface device 95 is used as an interface to connect to user input/output devices (touch panel, keyboard, mouse, etc.) or a network.

The control unit 90 may be configured by a host computer or a plurality of client computers that communicate information through a network. The substrate processing system 100 is not limited to a configuration in which each device is directly controlled by the control unit 90 but may also be configured such that it includes a dedicated control device (e.g., computer) for an appropriate apparatus (e.g., the substrate processing apparatus 1) and transmits a control command from the control unit 90 to the control device to allow the control device to control each apparatus.

### [Configuration for Performing Film Thickness Measuring Method]

The above substrate processing system 100 experiences a reduction in overall operational efficiency for substrate processing when extracting several substrates W after substrate processing to measure the film thickness outside the system without the measurement unit 150. Further, another film thickness measuring device needs to be installed outside the system, resulting in a reduction in footprint. Meanwhile, the substrate processing system 100 according to the present embodiment is configured to measure the thickness of a film formed on the substrate W by the measurement unit 150 during a period from taking the substrate W out of the wafer boat 16 and transferring the substrate W to the substrate storage container 161.

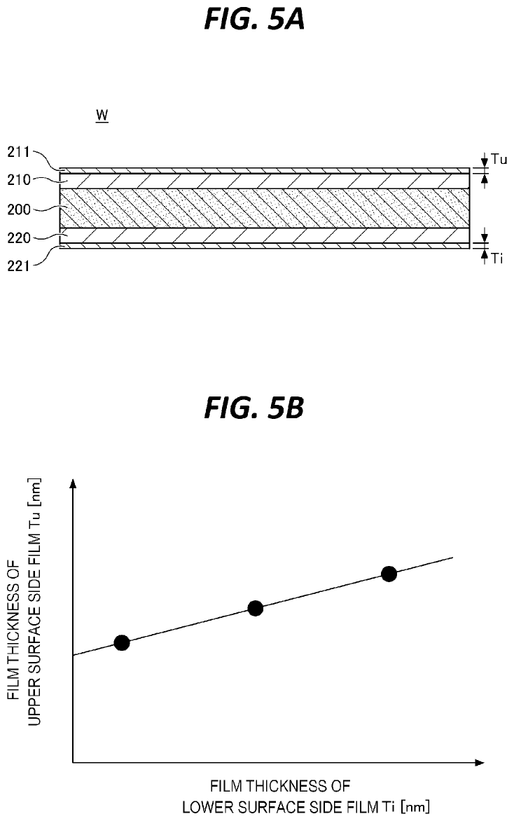

In particular, the substrate processing system 100 measures the thickness of a film formed on the lower surface of the substrate W by the measurement unit 150 to estimate the thickness of a film formed on the upper surface of the substrate W. Hereinafter, the principle of estimating the thickness of the film on the upper surface of the substrate W based on the thickness of the film on the lower surface of the substrate W will be described with reference to FIGS. 5A and 5B. FIG. 5A is a side cross-sectional view schematically illustrating the substrate W after substrate processing. FIG. 5B is a graph illustrating a relationship between the film thickness of a lower surface side film 221 and the film thickness of an upper surface side film 211.

For example, before substrate processing, the substrate W includes a base material 200, an upper surface side base film 210 stacked on the upper surface of the base material 200, and a lower surface side base film 220 stacked on the lower surface of the base material 200. This substrate W is subjected to substrate processing (film formation processing) while the outer edge thereof is held by the wafer boat 16. Therefore, the substrate W after substrate processing has the upper surface side film 211 above the upper surface side base film 210 and the lower surface side film 221 below the lower surface side base film 220, as illustrated in FIG. 5A.

However, the film thickness Tu of the upper surface side film 211 and the film thickness Ti of the lower surface side film 221, which are formed by substrate processing, may not necessarily be the same. This is because the state of film formation on the upper and lower surfaces of the substrate W varies depending on factors such as the type of film formed, the type of gas supplied during substrate processing, and other process conditions (e.g., temperature).

However, the substrate W, which is held by the wafer boat 16 and subjected to substrate processing, has a sufficient correlation between the film thickness Tu of the upper surface side film 211 and the film thickness Ti of the lower surface side film 211, as illustrated in FIG. 5B. In other words, as the film thickness Ti of the lower surface side film 221 of the substrate W increases, the film thickness Tu of the upper surface side film 211 also increases. Although FIG. 5B illustrates an example in which the film thickness Ti of the lower surface side film 221 and the film thickness Tu of the upper surface side film 211 increase linearly, this relationship may of course take various forms depending on the type of film, the type of gas, and other process conditions. In other words, the film thickness Tu of the upper surface side film 211 may increase nonlinearly with respect to the film thickness Ti of the lower surface side film 221.

The control unit 90 may estimate the film thickness Tu of the upper surface side film 211 based on the film thickness Ti of the lower surface side film 221 by holding information (functions, tables, etc.) indicating the correlation between the film thickness Tu of the upper surface side film 211 and the film thickness Ti of the lower surface side film 221. The information indicating the correlation between the film thickness Ti of the lower surface side film 221 and the film thickness Tu of the upper surface side film 211 may be prepared in advance through experiments or simulations, and may be calibrated as needed during the operation of the system.

The upper surface of the substrate W is typically formed with a pattern depending on semiconductor devices to be manufactured. When measuring the film thickness of the upper surface side film 211, even a slight misalignment of the measurement point may result in the measurement of the film thickness of the upper surface side film 211 at steps of the pattern, leading to measurement errors. Meanwhile, the lower surface of the substrate W is flat with no pattern formed, making it easy to measure the film thickness of the lower surface side film 221 after substrate processing. Thus, this leads to a reduction in measurement errors for film thickness measurement. Further, in the configuration in which film thickness measurement is performed on the lower surface of the substrate W, there is no need to install a film thickness measuring device for measuring the thickness of a film on the upper surface of the substrate W above the transfer path of the substrate W, thus reducing the generation of dust (particles) from the film thickness measuring device. Furthermore, the substrate processing system 100 may eliminate the influence of film modification caused by irradiating the upper surface side film 211 with the pattern formed thereon with measurement light.

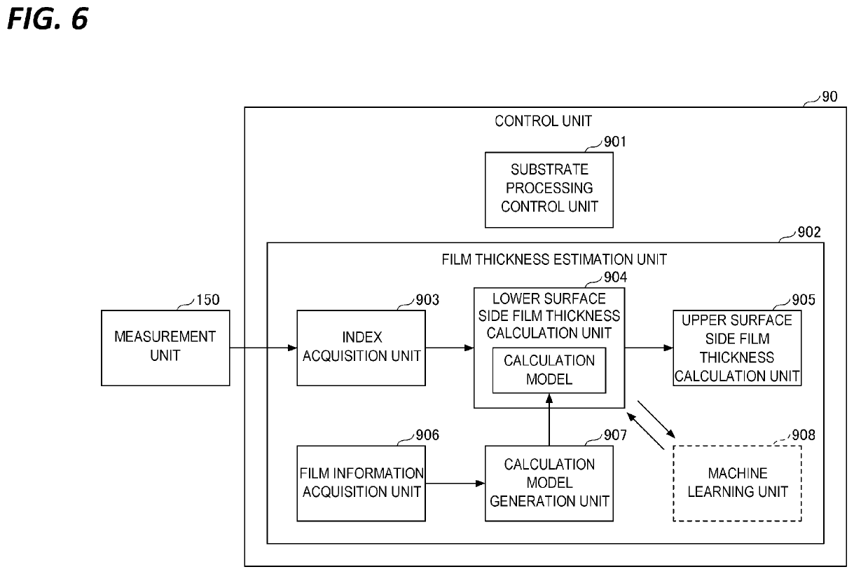

FIG. 6 is a block diagram illustrating functional parts in the control unit 90 that measures the film thickness of the substrate W. As illustrated in FIG. 6, the control unit 90 internally forms a substrate processing control unit 901 and a film thickness estimation unit 902 under the execution of a program. The substrate processing control unit 901 and the film thickness estimation unit 902 may be configured by separate computers.

The substrate processing control unit 901 controls the above-described substrate processing apparatus 1, boat actuator 110, boat stage 120, boat transfer unit 130, substrate transfer unit 140, interface 160, load port 170, and others to perform substrate processing on each substrate W.

Meanwhile, the film thickness estimation unit 902 further internally contains an index acquisition unit 903, lower surface side film thickness calculator 904, upper surface side film thickness estimation unit 905, film information acquisition unit 906, and calculation model generation unit 907.

The index acquisition unit 903 controls the measurement unit 150 to measure an index related to the lower surface side film thickness of the substrate W during the transfer of the substrate W, thus acquiring the measured index related to the film thickness from the measurement unit 150. As described above, the index related to the film thickness is information on the wavelength (frequency) and reflection intensity of the reflection spectrum of the measurement light reflected from the lower surface of the substrate W (see also FIG. 3A).

The index related to the film thickness of the substrate W may be acquired at a predetermined point (e.g., the center) on the substrate W, or may be acquired at a plurality of predetermined points on the substrate W. Alternatively, the measurement unit 150 may continuously perform film thickness measurement while the substrate transfer unit 140 is transferring the substrate W. For example, the measurement unit 150 may acquire an index related to the distribution of film thickness on the radius of the substrate W by performing film thickness measurement within the radial range WR (see FIG. 3B) from the outer edge to the center of the substrate W.

The lower surface side film thickness calculator 904 calculates the film thickness of the lower surface side film 221 using the index related to the film thickness acquired by the index acquisition unit 903. A calculation method for calculating the film thickness of the lower surface side film 221 is not particularly limited but, for example, a calculation model (CM) is used to simulate the film thickness. The calculation model (CM) is generated in advance as a simulation model with a reflection spectrum as a variable, based on the physical properties of a film to be formed, the reflection spectrum (index related to the film thickness), and the actual film thickness corresponding to the reflection spectrum. The physical properties of the film to be formed are fixed values that affect the film thickness of the film during film formation. Examples of these physical properties may include optical properties (reflectance and transmittance), thermal conductivity, electrical conductivity, heat resistance, strength, hardness, resistance, insulation, dielectric constant, etching ratio, and others.

The film information acquisition unit 906 acquires and stores the physical properties of the film to be formed, for example, through user input or via a network, and then provides them to the calculation model generation unit 907. Alternatively, the film information acquisition unit 906 may acquire updated physical properties of the film, measured reflection spectrum, and film thickness (measured by another film thickness meter) in the course of operating the substrate processing system 100, and may provide them to the calculation model generation unit 907.

The calculation model generation unit 907 generates the calculation model (CM) based on the physical properties of the film, reflection spectrum, film thickness, and others from the film information acquisition unit 906. The calculation model generation unit 907 may automatically calibrate the calculation model (CM) under user operation, upon update of film information, or periodically. This ensures more accurate measurement of the film thickness of a lower surface side film of the substrate W.

Further, the upper surface side film thickness estimation unit 905 calculates (estimates) the film thickness of the upper surface side film 211 based on the film thickness of the lower surface side film 221 of the substrate W calculated by the lower surface side film thickness calculator 904. The upper surface side film thickness estimation unit 905 may use information (e.g., functions and tables) indicating the correlation between the film thickness of the lower surface side film 221 and the film thickness of the upper surface side film 211 to calculate the film thickness of the upper surface side film 211 (see also FIG. 5B).

The film thickness estimation unit 902 of the control unit 90 is not limited to using the above-described calculation model (CM) for calculating the film thickness from the reflection spectrum but may employ various other methods. For example, the film thickness estimation unit 902 may contain a machine learner 908 (see the dotted line in FIG. 6), and by training the machine learner 908 with the reflection spectrum and thickness acquired in the past, may predict the film thickness from these machine learning parameters as well as the reflection spectrum acquired this time. The film thickness prediction using machine learning may employ algorithms such as linear multiple regression, Lasso, Ridge, Elastic Net, PLS, and Genetic Algorithm, and others as appropriate.

Further, the machine learner 908 may enhance the accuracy of film thickness calculation based on the reflection spectrum by deep learning the feature extraction of the reflection spectrum using a neutral network.

### [Film Thickness Measuring Method]

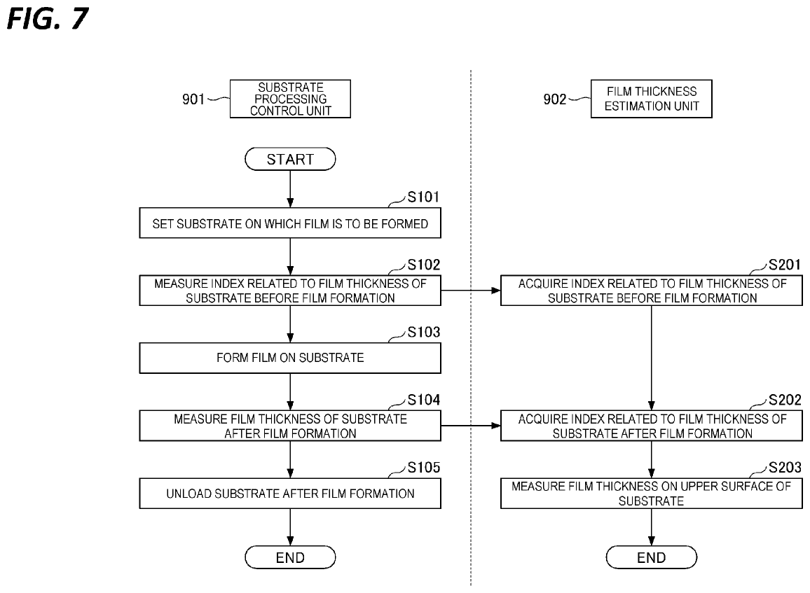

The substrate processing system 100 according to the present embodiment is basically configured as described above, and the operation (film thickness measuring method) thereof will be described below. FIG. 7 is a flowchart illustrating the processing flow of a film thickness measuring method. Steps S101 to S105 and S201 to S203 in FIG. 7 are performed under the control of the control unit 90.

The substrate processing control unit 901 of the control unit 90 controls the substrate transfer unit 140, interface 160, and load port 170 of the substrate processing system 100 to load the substrate W into the wafer boat 16 and support a plurality of substrates W by the wafer boat 16 (step S101). At this time, the substrate processing control unit 901 ensures that, before transferring the substrate W from the port 163 of the interface 160 to the wafer boat 16 on the boat stage 120, the substrate W is directed to pass through the measurement unit 150 by the substrate transfer unit 140.

Then, the substrate processing control unit 901 emits measurement light to the lower surface of the substrate before film formation by the measurement unit 150 to measure the resulting reflection spectrum (index related to the film thickness) (step S102). In other words, in the film thickness measurement of the substrate W, using the reflection spectrum of the substrate W before film formation may lead to more accurate measurement of the film thickness of the substrate W after film formation.

Once each substrate W has been completely set in the wafer boat 16, the substrate processing control unit 901 operates the boat transfer unit 130 and the boat actuator 110 to load the wafer boat 16 into the processing container 10, and after this transfer, performs substrate processing by the substrate processing apparatus 1 (step S103). Accordingly, each substrate W supported by the wafer boat 16 has the upper surface side film 211 formed on the upper surface and the lower surface side film 221 formed on the lower surface thereof. Then, once the substrate processing apparatus 1 has completed substrate processing, the substrate processing control unit 901 operates the boat actuator 110 and the boat transfer unit 130 to unload the wafer boat 16 from the processing container 10 and place the wafer boat 16 on the boat stage 120.

Furthermore, the substrate processing control unit 901 operates the substrate transfer unit 140 to take out each substrate W supported by the wafer boat 16 and to transfer the substrate W to the port 163. At this time, the substrate processing control unit 901 controls the substrate transfer unit 140 to transfer the substrate W by way of the measurement unit 150 and the measurement unit 150 to emit measurement light to the lower surface of the substrate W after film formation, thus measuring the resulting reflection spectrum (index related to the film thickness) (step S104). This enables the control unit 90 to efficiently acquire the reflection spectrum of each substrate W after film formation.

Finally, the substrate processing control unit 901 controls the operation of the interface 160 and load port 170 to unload the substrate storage container 161, which accommodates the substrate W after film formation, to the outside of the substrate processing system 100 (step S105).

By repeating the processing flow of the above steps S101 to S105, the substrate processing control unit 901 may sequentially acquire the index related to the film thickness of the substrate W after film formation while forming a desired film on each substrate W.

Meanwhile, the film thickness estimation unit 902 of the control unit 90 first acquires the reflection spectrum (index related to the film thickness) of the substrate W before film formation measured by the measurement unit 150 in step S102 (step S201). Thereafter, the film thickness estimation unit 902 acquires the reflection spectrum (index related to the film thickness) of the substrate W after film formation measured by the measurement unit 150 in step S104 (step S202).

Then, the film thickness estimation unit 902 calculates the film thickness of the lower surface side film 221 of the substrate W using the reflection spectrum of the substrate W before film formation and the reflection spectrum of the substrate W after film formation, and estimates the film thickness of the upper surface side film 211 based on the film thickness of the lower surface side film 221 (step S203).

Here, in the film thickness measurement of the substrate W before film formation in step S102, an interference pattern is formed by the reflected measurement light from the surface of the lower surface side base film 220 and the reflected measurement light from the boundary between the base material 200 and the lower surface side base film 220. In the film thickness measurement of the substrate W after film formation in step S104, an interference pattern is formed by the reflected measurement light from the surface of the lower surface side film 221 and the reflected measurement light from the boundary between the lower surface side base film 220 and the lower surface side film 221. However, the film thickness measurement of the substrate W after film formation may involve the reflected measurement light that passes through the lower surface side base film 220 and is reflected from the boundary between the base material 200 and the lower surface side base film 220.

Therefore, the film thickness estimation unit 902 eliminates the influence of the film thickness of the lower surface side base film 220 on the reflection spectrum of the substrate W after film formation using the reflection spectrum of the substrate W before film formation. This allows the film thickness estimation unit 902 to accurately calculate only the film thickness of the lower surface side film 221 based on the calibrated reflection spectrum.

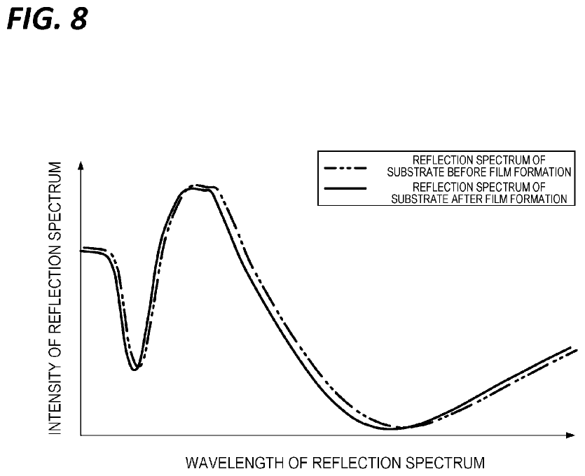

FIG. 8 is a graph illustrating the reflection spectrum of the substrate W measured by the measurement unit 150. In the graph of FIG. 8, the horizontal axis is the wavelength of the reflection spectrum, and the vertical axis is the reflection intensity of the reflection spectrum. Further, the solid line indicates the reflection spectrum of the substrate W after film formation, and the two-dot dashed line is the reflection spectrum of the substrate W before film formation.

As illustrated in FIG. 8, the reflection spectrum of the substrate W before film formation and the reflection spectrum of the substrate W after film formation exhibit continuous spectra but are shifted from each other in terms of wavelength and reflection intensity. By analyzing this shift in terms of wavelength and reflection intensity, the film thickness estimation unit 902 may calibrate the reflection spectrum depending on the film thickness of the lower surface side film 221. The reflection spectrum of the substrate W before film formation and the reflection spectrum of the substrate W after film formation are not limited to an overall shift but may exhibit different partial shifts for each wavelength zone. Even in this case, the lower surface side film thickness calculator 904 of the film thickness estimation unit 902 may calibrate the reflection spectrum of the substrate W after film formation by extracting the degree of shift for each wavelength with a large reflection intensity. Then, the lower surface side film thickness calculator 904 may acquire the film thickness of the lower surface side film 221 by simulating the calibrated reflection spectrum using the above-described calculation model (CM) or machine learning parameters.

Furthermore, the upper surface side film thickness estimation unit 905 estimates the film thickness of the upper surface side film 211 based on the calculated film thickness of the lower surface side film 221, as described above. This allows the film thickness estimation unit 902 to easily and accurately estimate the thickness of the film on the upper surface of the substrate W having a semiconductor device pattern.

The substrate processing system 100 and the film thickness measuring method are not limited to the above-described configuration but may employ various other configurations. For example, the substrate processing system 100 applies the spectroscopic interference film thickness meter to the configuration of the measurement unit 150 but may apply various other measuring devices without a limitation thereto. For the index related to the film thickness of the substrate W, appropriate information may be employed according to the measuring method of the measuring device.

Further, in the above-described embodiment, both the indices related to the film thickness of the substrate W before film formation and the film thickness of the substrate W after film formation were used to calculate the film thickness after the formation of films (both upper surface side and lower surface side films). However, the substrate processing system 100 and the film thickness measuring method may be configured to calculate the film thickness after film formation using only the index related to the film thickness of the substrate W after film formation.

Further, for example, the substrate processing system 100 may perform etching on a film of the substrate W using an etching-based substrate processing apparatus, and after this etching, may measure an index related to the lower surface side film thickness of the substrate W by the measurement unit 150, thus calculating the film thickness of films (both upper surface side and lower surface side films).

### SUMMARY

The technical ideas and effects of the present disclosure described in the above embodiment will be described below.

A first aspect of the present disclosure is a substrate processing system 100 including a substrate support (wafer boat 16) that supports an outer edge of a substrate W having a first surface (upper surface) and a second surface (lower surface) opposite to the first surface, a processing container 10 that accommodates the substrate W and the substrate support to perform a substrate processing on the substrate W, and a substrate transfer unit 140 that transfers the substrate subjected to the substrate processing. The substrate processing system further includes a measurement unit 150 that is provided on a transfer path along which the substrate W is transferred by the substrate transfer unit 140 and that measures an index related to a film thickness of a film stacked on the second surface, and a film thickness estimation unit 902 that calculates the film thickness of the film on the second surface based on the measured index related to the film thickness of the film on the second surface and to calculate a film thickness of a film stacked on the first surface based on the calculated film thickness of the film on the second surface.

According to the above, the substrate processing system 100 may efficiently and accurately measure the film thickness of the substrate by using the index related to the film thickness on the second surface (lower surface) of the substrate W measured by the measurement unit 150. In other words, the substrate W exhibits a correlation between the film thickness of the film on the first surface (upper surface) and the film thickness of the film on the second surface, and the film thickness of the film on the first surface may be accurately calculated based on the film thickness of the film on the second surface. This allows the substrate processing system 100 to obtain a highly accurate film thickness without significantly impeding the transfer of the substrate W, enabling the recognition of the status of substrate processing and others.

Further, the measurement unit 150 irradiates the second surface (lower surface) with measurement light, and measures a reflection spectrum of reflected light from the second surface as the index related to the film thickness. By using the reflection spectrum of the second surface, the substrate processing system 100 may simplify the generation of a model to calculate the film thickness and may also reduce the impact on semiconductor devices on the first surface.

Further, the film thickness estimation unit 902 acquires the reflection spectrum of the second surface (lower surface) before the substrate processing is performed, and acquires the reflection spectrum of the second surface after the substrate processing is performed, thereby calibrating the reflection spectrum of the second surface after the substrate processing is performed, using the reflection spectrum of the second surface before the substrate processing is performed. This allows the substrate processing system to remove noise in the reflection spectrum of the second surface after the substrate processing, enabling more accurate calculation of the film thickness of the film on the second surface.

Further, the film thickness estimation unit 902 calculates the film thickness of the film on the second surface based on a calculation model (CM) held in advance and the acquired reflection spectrum of the second surface (lower surface). As such, the substrate processing system 100 may more accurately acquire the film thickness of the film on the second surface by using the calculation model (CM).

Further, the film thickness estimation unit 902 performs machine learning on the reflection spectrum of the second surface (lower surface) acquired in the past to calculate the film thickness of the film on the second surface based on a result of the machine learning and the reflection spectrum of the second surface acquired this time. Even in this case, the substrate processing system 100 may accurately acquire the film thickness of the film on the second surface and may derive the film thickness with fewer parameters than when using the calculation model CM.

Further, the film thickness estimation unit 902 holds information indicating a correlation between the film thickness of the film on the first surface (upper surface) and the film thickness of the film on the second surface (lower surface) in advance, and calculates the film thickness of the film on the first surface based on the information indicating the correlation and the calculated film thickness of the film on the second surface. This allows the substrate processing system to easily obtain the film thickness of the film on the first surface from the film thickness of the film on the second surface.

Further, the measurement unit 150 is provided between the substrate storage container 161 that stores the substrate and the substrate support (wafer boat 16) and below the transfer path of the substrate W transferred by the substrate transfer unit 140 to measure the second surface of the substrate W while the substrate is being transferred by the substrate transfer unit 140. This allows the substrate processing system 100 to easily obtain the film thickness of the first surface of the substrate W while the substrate W is being transferred. Moreover, since the measurement unit 150 may be mounted on an existing apparatus, it does not require an additional footprint in the system, contributing to a reduction in footprint.

Further, the processing container 10 accommodates the substrate support (wafer boat 16) supporting a plurality of substrates W to perform the substrate processing, and the substrate transfer unit 140 takes out the substrate W from the substrate support after implementation of the substrate processing to transfer the substrate to the substrate storage container 161. This allows the substrate processing system 100 to measure the film thickness of each substrate W taken out from the substrate support, thereby reducing the number of substrates W with an unknown film thickness, compared to a configuration in which the substrate W is taken out for inspection.

Further, a second aspect of the present disclosure is a film thickness measuring method including supporting an outer edge of a substrate having a first surface (upper surface) and a second surface (lower surface) opposite to the first surface by a substrate support (wafer boat 16) (step S101), accommodating the substrate W and the substrate support in the processing container 10 to perform a substrate processing on the substrate W (step S103), transferring the substrate W subjected to the substrate processing by the substrate transfer unit 140, measuring an index related to a film thickness of a film stacked on the second surface by the measurement unit 150 provided on a transfer path along which the substrate W is transferred by the substrate transfer unit 140 (step S104), and calculating the film thickness of the film on the second surface based on the measured index related to the film thickness of the film on the second surface and calculating a film thickness of a film stacked on the first surface based on the calculated film thickness of the film on the second surface (step S203).

According to an aspect, it is possible to efficiently and accurately measure the film thickness of a substrate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing system comprising:
a substrate support configured to support an outer edge of a substrate having a first surface and a second surface opposite to the first surface;
a processing container configured to accommodate the substrate and the substrate support to perform a substrate processing on the substrate; and
a substrate transfer unit including a robot configured to transfer the substrate subjected to the substrate processing,
wherein the substrate processing system further comprises:
a measurement unit including a meter provided on a transfer path along which the substrate is transferred by the substrate transfer unit and configured to measure an index related to a film thickness of a film stacked on the second surface; and
an estimation unit including a calculator configured to calculate the film thickness of the film on the second surface based on the measured index related to the film thickness of the film on the second surface and to calculate a film thickness of a film stacked on the first surface based on the calculated film thickness of the film on the second surface.

2. The substrate processing system according to claim 1, wherein the measurement unit irradiates the second surface with measurement light, and measures a reflection spectrum of reflected light from the second surface as the index related to the film thickness of the film on the second surface.

3. The substrate processing system according to claim 2, wherein the estimation unit acquires the reflection spectrum of the second surface before the substrate processing is performed, and acquires the reflection spectrum of the second surface after the substrate processing is performed, thereby calibrating the reflection spectrum of the second surface after the substrate processing is performed, using the reflection spectrum of the second surface before the substrate processing is performed.

4. The substrate processing system according to claim 2, wherein the estimation unit calculates the film thickness of the film on the second surface based on a calculation model held in advance and the acquired reflection spectrum of the second surface.

5. The substrate processing system according to claim 2, wherein the estimation unit performs machine learning on the reflection spectrum of the second surface acquired in a past to calculate the film thickness of the film on the second surface based on a result of the machine learning and the reflection spectrum of the second surface acquired this time.

6. The substrate processing system according to claim 1, wherein the estimation unit holds, in advance, information indicating a correlation between the film thickness of the film on the first surface and the film thickness of the film on the second surface, and calculates the film thickness of the film on the first surface based on the information indicating the correlation and the calculated film thickness of the film on the second surface.

7. The substrate processing system according to claim 1, wherein the measurement unit is provided between a substrate storage container that stores the substrate and the substrate support and below the transfer path of the substrate transferred by the substrate transfer unit to measure the second surface of the substrate while the substrate is being transferred by the substrate transfer unit.

8. The substrate processing system according to claim 7, wherein the processing container accommodates the substrate support that supports a plurality of substrates to perform the substrate processing, and
wherein the substrate transfer unit takes out the substrate from the substrate support after the substrate processing is performed, and transfers the substrate to the substrate storage container.

9. A film thickness measuring method comprising:
supporting an outer edge of a substrate having a first surface and a second surface opposite to the first surface by a substrate support;
accommodating the substrate and the substrate support in a processing container to perform a substrate processing on the substrate;
transferring the substrate subjected to the substrate processing by a substrate transfer unit including a robot;
measuring an index related to a film thickness of a film stacked on the second surface by a measurement unit including a meter provided on a transfer path along which the substrate is transferred by the substrate transfer unit; and
calculating the film thickness of the film on the second surface based on the measured index related to the film thickness of the film on the second surface, and calculating a film thickness of a film stacked on the first surface based on the calculated film thickness of the film on the second surface.
